(19) United States
(12) Patent Application Publication
(10) Pub. No.: US 2014/0061728 A1
(43) Pub. Date: Mar. 6, 2014

(54) Gate Biasing Electrodes For FET Sensors

(71) Applicant: Diagtronix Inc., Dallas, TX (US)

(72) Inventor: Krutarth Trivedi, Plano, TX (US)

(73) Assignee: Diagtronix Inc., Dallas, TX (US)

(21) Appl. No.: 14/014,219

(22) Filed: Aug. 29, 2013

Related U.S. Application Data
(60) Provisional application No. 61/694,670, filed on Aug. 29, 2012.

(51) Int. Cl. H01L 29/78; H01L 29/66

(52) U.S. Cl. CPC H01L 29/785; H01L 29/66484
USPC 257/253; 438/49

(57) ABSTRACT

A FET sensor with a gate biasing electrode is disclosed in one embodiment. In another embodiment, a process for forming a finFET sensor with a polysilicon gate biasing electrode is disclosed. In a further embodiment, a process for forming a finFET sensor with a single crystal gate biasing electrode is disclosed.

This application claims the benefit of U.S. Provisional Application No. 61/694,670, filed on Aug. 29, 2012, entitled Gate Electrodes for FET Sensors, which application is hereby incorporated herein by reference.

### BACKGROUND

Molecular detection is sometimes accomplished by optical techniques such as Enzyme Linked Immunoassay (ELIZA). However, the overall complexity and high cost, limited sensitivity, and lack of portability, can make utilization of such methods for point-of-care applications difficult. Alternatively, semiconductor field effect transistor (FET) based sensors offer rapid, low-cost, and direct detection of a variety of target entities with high sensitivity and specificity. Ion-sensitive field effect transistors (ISFETs) are an example of semiconductor devices that measure variations in surface charge distribution on exposed gate dielectric of a FET. To maximize sensitivity of a FET, the FET may be biased into the subthreshold region where a linear change in gate voltage causes an exponential change in drive current through the FET. In ISGETS typically bias is applied to the channel of the transistor by inserting a biasing wire coated with Ag/Agcl into the liquid.

### SUMMARY OF THE INVENTION

In accordance with an embodiment of the present invention, a FET sensor comprises a gate biasing electrode in a fluid path of said FET sensor. In another embodiment, a process for forming a finFET sensor with a polysilicon gate biasing electrode is disclosed. In a further embodiment, a process for forming a finFET sensor with a single crystal gate biasing electrode is disclosed.

### BRIEF DESCRIPTION OF THE DRAWINGS

For a more complete understanding of the present invention, and the advantages thereof, reference is now made to the following descriptions taken in conjunction with the accompanying drawing, in which:

FIG. 1, which includes FIGS. 1A and 1B, illustrates structural configuration of a patterned gate biasing electrode in accordance with an embodiment of the present invention; and

FIG. 2, which includes FIGS. 2A-2C, illustrates cross sectional views of the gate biasing electrode composed of two layers in accordance with alternative embodiments of the present invention.

The following list of reference symbols may be used in conjunction with the drawings:

### DETAILED DESCRIPTION OF ILLUSTRATIVE EMBODIMENTS

Some structures and/or methods described in U.S. Provisional Patent Application No. 61/675,681 (the '681 application), filed on Jul. 25, 2012 and incorporated by reference herein, may be suitable for making or using similar structures and/or methods of the present application.

In FET biosensors, the surface of the gate dielectric may be modified with linker molecules for capture of specific target entities from solution, upon which the conductance of the FET channel may change in proportion to the net charge of captured targets. The FET sensor may first be biased into the sub-threshold region, where a linear change in charge causes a logarithmic change in channel current for maximum sensitivity. The baseline conductance may be established by a gate biasing electrode in solution that biases the FET sensor through the solution and gate dielectric. As charged entities attach to the linker molecules on the gate dielectric, the resulting electric field through the gate dielectric may alter the baseline conductance by shifting the threshold voltage of the FET sensor, resulting in change in channel current. Typically, gating of FET sensors through solution is achieved by inserting a metal biasing wire, as a reference electrode, into the solution flowing on top of the channel of the FET sensor. However, this configuration limits utility of FET sensors in point-of-care (POC) or portable applications, in which compact form factor and ease of use may be advantageous. Moreover, adsorption of biomolecules on the gate electrode would tend to contaminate the electrode's surface. In addition of the external metal wire reference electrode adds cost to the packaging process.

In some applications a FET sensor may be exposed to solutions having, e.g. a wide range of pH, and/or contain salts and/or other ionic species that can cause corrosion and/or electrochemical redox reactions that could otherwise result in contamination of the solution, damage to the gate electrode and/or degraded electrical properties and performance of the sensor. Therefore, it may be difficult to use non-noble metals as gate biasing electrodes of FET sensors, as they usually etch spontaneously in strong oxidizing environments. In some cases it may be preferable that the gate electrode be chemically inert, e.g. chemically substantially nonreactive with chemical species that the gate electrode may be exposed to. It may also be desirable that the gate biasing electrode material be compatible with oxidizing solutions used to clean the critical gate dielectric of FET sensors prior to surface modification with linker molecules. Typically, silver chloride (AgCl) biasing wires are used as reference electrodes to bias FET sensors through solution. Noble metals such as gold (Au) or platinum (Pt) may be used as gate biasing electrodes and could potentially be patterned directly onto the sensor chip during the chip manufacturing process using conventional semiconductor processing techniques. However, it may not be practical to use Au, Pt, or other noble metals due to increased cost of adding processing steps for the noble metals, incompatibility with FET sensor cleaning procedures or operating conditions and/or incompatibility with semiconductor manufacturing protocols. Therefore, incorporation of a gate biasing electrode, which is lithographically patterned on the sensor chip along with FET sensors, while considering chemical and processing compatibility, contamination, as well as economic feasibility, remains a significant challenge. Ideally a gate biasing electrode would be formed during manufacture of the FET sensor with no added cost.

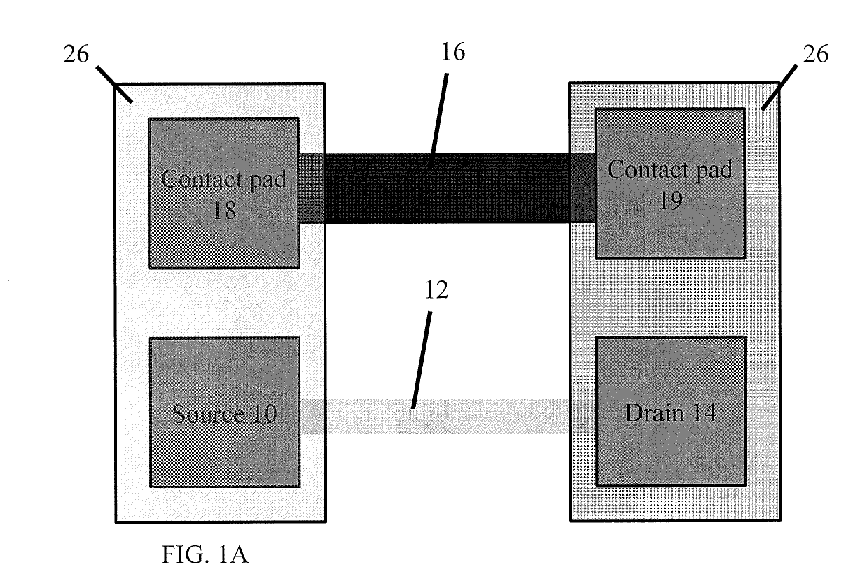

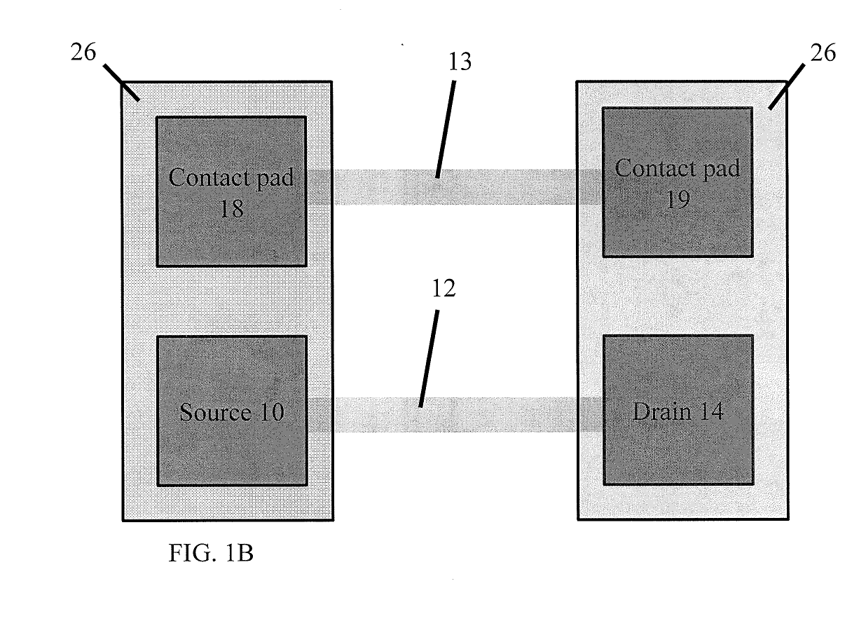

To address some of the aforementioned issues, embodiments of the invention include gate electrode(s) of a FET sensor and methods of forming such gate biasing electrodes. The gate biasing electrodes may be formed on the sensor chip during fabrication of the FET sensor with no additional manufacturing steps. The embodiment in FIG. 1A illustrates one structural configuration of the patterned gate biasing electrode, which may be located in the fluid path, near the channel(s) of the FET sensor(s), which may include a single-channel finFET device or a multiple-channel finFET. Single-channel finFET devices are described in, e.g., PCT Application Publication WO 2012/050873 (“the '873 application), incorporated herein by reference in its entirety. Multi-channel finFET devices are described in, e.g., U.S. patent application Ser. No. 13/590,597 (“the '597 application”), incorporated herein by reference in its entirety. The channel(s) 12 of the FET sensor, which may be covered by gate dielectric and/or protective and conductive layers as described in the '681 application, is shown between source 10 and drain 14. A gate biasing electrode 16 is shown connected to conductive contact pads 18 and 19. The contact pads 18 and 19 may be fabricated from the same material as the gate electrode 16. In the completed FET sensor, contact pads 18 and 19 of the gate biasing electrode 16, and source and drain pads 10 and 14 of the FET sensor 12 may be covered by a layer of passivation material 26 such that only the gate biasing electrode 16 and the channel 12 of the FET sensor 12 are exposed to solution. The gate biasing electrode 16 may be doped polysilicon, silicided polysilicon, or may be a gate biasing electrode made of metal.

The embodiment in FIG. 1B illustrates another structural configuration of the patterned gate biasing electrode, which may be located in a path of a fluid sample being tested, near the channel(s) of the FET sensor(s), which may be a single channel finFET or a multiple-channel finFET, as respectively described in the described in the '873 and '597 applications. In this embodiment, the channel(s) 13 of an adjacent device is (are) utilized as gate biasing electrode; the channel(s) 13 is (are) formed in the same manner as the channels of a FET sensor device, as described in the '873 application and/or the '597 application. A singular bias is applied to both contact pads 18 and 19, thereby holding the channel(s) at the applied bias. The contact pads 18 and 19 may be metalized pads formed on silicon that is doped at the same level as the channel(s) to avoid formation of any doping gradients or junctions. Additionally, a metal silicide may be formed on the silicon underneath contact pads 18 and 19; alternatively, contact pads 18 and 19 could be composed of the metal silicide alone. (Likewise a metal silicide may be formed on the gate biasing electrode 13; alternatively the gate biasing electrode could be composed of the metal silicide alone. In both embodiments 1A and 1B, the contact pads 18 and 19, and the source and drain pads 10 and 14, may be covered by an insulating material, forming a passivation layer 26 that protects them from exposure to the sample fluid. The passivation layer 26 may then be covered with a coating of self-assembled molecules (SAMs) such as silanes followed by chemistry to reduce non-specific binding, porous hydrophilic materials such as Nafion or hydrophilic polyurethane or proteins like bovine serum albumin (BSA) for anti-bio-fouling properties or ion exchange or ion selective membranes or resins for regulation of ions which the gate electrode is exposed to. This coating may also be formed covering the topmost layer of the gate basing electrode 16 or 13 (FIG. 1A,1B), which may also be exposed to solution fluid sample.

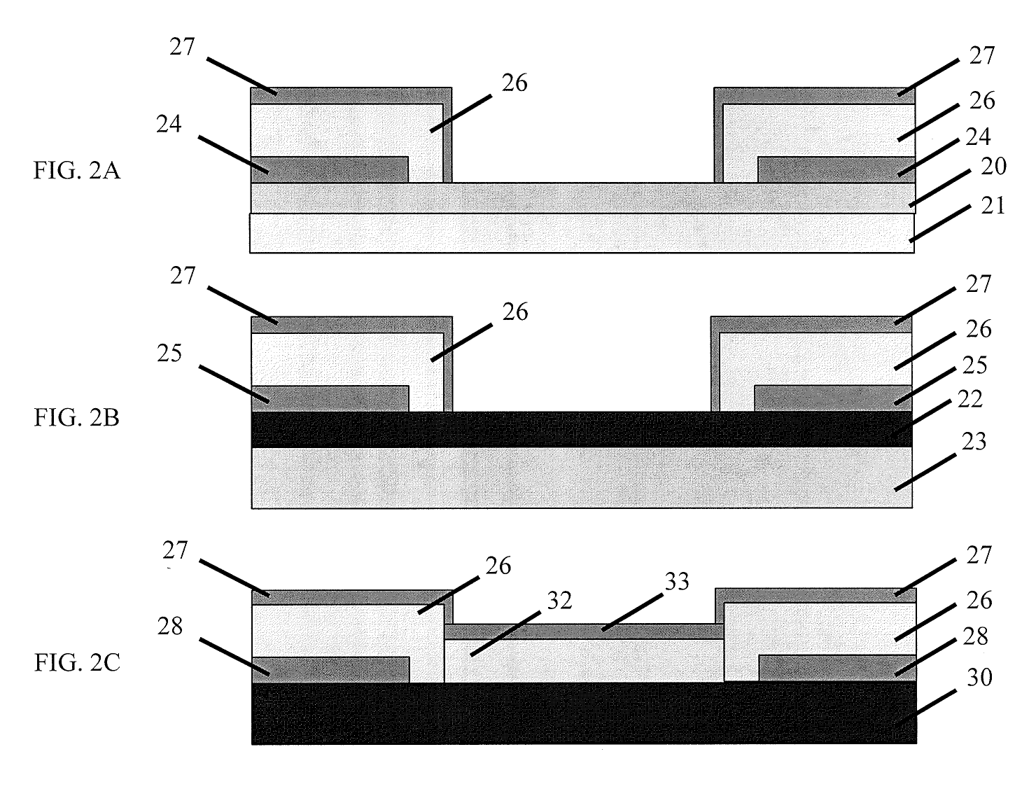

One embodiment, shown in FIG. 2A and relating to the structure shown in FIG. 1A, shows a cross section of the gate biasing electrode composed of two layers, 20 and 21. The first layer of the gate electrode 21 is patterned from the top single crystalline silicon layer of the silicon or silicon-on-insulator wafer. The second layer 20 is a layer of conductive material such as poly-silicon, which may be doped with either n or p type dopants; the layer of poly-silicon 20 may be formed simultaneously with the protection layer 26, described in the '681 application. During subsequent removal of the protection layer 26 before surface functionalization, as described in the '681 application, a portion of the protection layer of poly-silicon 20 not covering the channel(s) 12 (FIG. 1A) of the sensor can be selectively patterned to remain in between devices or somewhere within the fluid channel to serve as the gate biasing electrode. The conductive contact pads 2 are one representation of pads 18 and 19 in FIG. 1A and may be formed by contacting the gate biasing poly-silicon 20 with a contact metal such as for example, aluminum. The conductive contact pads 2 may be covered by an insulating material, forming a passivation layer 26 that protects the pads 2 from exposure to solution. The passivation layer 26 may be covered with a coating 27 of self-assembled molecules (SAMs) such as silanes, hydrophilic layers such as Nafion or hydrophilic polyurethane or proteins like bovine serum albumin (BSA) for anti-bio-fouling properties; this coating 27 may also be formed atop the gate biasing electrode's topmost layer 20.

In another embodiment, shown in FIG. 2 and relating to the structures shown in FIGS. 1A and 1B, a layer of metal silicide 22 can be formed on top of the poly-silicon biasing gate electrode layer 23. The biasing gate electrode may be formed on a polysilicon protection layer 20 such as is illustrated in FIG. 1A or may be formed on single crystal biasing gate electrode such as is illustrated in FIG. 1B. The silicide may be formed with any metal including, but not limited to, nickel, titanium, tantalum, tungsten, molybdenum or cobalt. The silicide also forms a good electrical contact with the conductive contact pads 25. The contact pads 25 could be formed with a contact metal such as for example, aluminum or could be patterned simultaneously with and of the same material as the conductive layer described in the '681 application. The conductive contact pads 25 are one representation of pads 18 and 19 in FIGS. 1A and 1B. The conductive contact pads 25 may be covered by an insulating material, forming a passivation layer 26 that protects the contact pads 25 from exposure to solution. The passivation layer 26 may be covered with a coating 27 of self-assembled molecules (SAMs) such as silanes followed by chemistry to reduce non-specific binding, porous hydrophilic layers such as Nafion or hydrophilic polyurethane or proteins like bovine serum albumin (BSA) for anti-bio-fouling properties or ion exchange or ion selective membranes or resins; this coating may also be formed atop the gate electrode's topmost layer 22.

In another embodiment, shown in FIG. 2C and relating to the structure shown in FIG. 1A, the gate biasing electrode 30 may be formed by any metal, doped/undoped poly-silicon, doped/undoped single crystalline silicon, metal silicide or the conductive layer described in the '681 application. To protect the gate biasing electrode from solution, a conformal layer of insulating material 32 such as polyimide or similar resist is patterned on top of the gate biasing electrode, particularly the portion of the gate biasing electrode exposed to fluid. This insulating layer 32 may be patterned simultaneously with and of the same material as passivation layer 26 or other insulating material deposited with techniques including but not limited to chemical vapor deposition, atomic layer deposition, or sputtering such that the layer of insulating material 32 is exposed to solution. The insulating layer 32 and the passivation layer 26 may be covered with coatings, 27 and 33, of self-assembled molecules (SAMs) such as silanes followed by chemistry to reduce non-specific binding, porous hydrophilic layers such as Nafion or hydrophilic polyurethane or proteins like bovine serum albumin (BSA) for anti-bio-fouling properties or ion exchange or ion selective membranes or resins; coatings 27 and 33 may be combined into a single coat of the same material.

The patterned polysilicon or silicide layers may act as conductive traces for a metalized gate electrode, thereby minimizing the total area of the metalized gate electrode. An inert noble metal such as gold or platinum may be deposited on the patterned polysilicon or silicide layers of the gate electrode. Alternatively, metals forming native metal oxides such as aluminum, nickel, tin etc may also be used as metalized gates. The native or thermally grown metal oxide on such metals may be coated with self-assembled molecules (SAMs) such as silanes followed by chemistry to reduce non-specific binding, porous hydrophilic layers such as Nafion or hydrophilic polyurethane or proteins like bovine serum albumin (BSA) for anti-bio-fouling properties or ion exchange or ion selective membranes or resins. Alternatively, silver may be deposited on top of the polysilicon or silicide layers of the patterned gate electrode, followed by formation of silver chloride by chorine plasma or chemicals such as sodium hypochlorite or bleach. The metalized or silver chlorided gate electrodes may also be coated with porous hydrophilic layers such as Nafion or hydrophilic polyurethane or proteins like bovine serum albumin (BSA) for anti-bio-fouling properties or ion exchange or ion selective membranes or resins.

Embodiments of the invention are expected to enable cost-effective fabrication of gate electrodes directly onto the sensor chip with methods compatible with semiconductor manufacturing protocols and surface chemistry and bio-conjugation procedures, allowing for integration of sensor chips into simpler and compact form factors.

What is claimed is:

1. A FET sensor comprising a gate biasing electrode disposed in a fluid path of said FET sensor.

2. The FET sensor of claim 1 where said gate biasing electrode is polysilicon.

3. The FET sensor of claim 1 where said gate biasing electrode is silicided polysilicon.

4. The FET sensor of claim 1 where said gate biasing electrode is silicided single crystal silicon.

5. The FET sensor of claim 1 where said gate biasing electrode is covered with a layer of insulating material.

6. The FET sensor of claim 5 where said layer of insulating material is polyimide.

7. The FET sensor of claim 1 where said gate biasing electrode is coated with a passivation layer.

8. The FET sensor of claim 7 where said passivation layer is a silane or a hydrophilic layer such as Nafion or a hydrophilic polyurethane or a protein.

9. The FET sensor of claim 8 where said protein is bovine serum albumin.

10. The FET sensor of claim 1 where said FET sensor is a finFET sensor.

11. A process for forming a FET sensor with a gate biasing electrode comprising the steps:
providing a silicon on insulator wafer;
forming an active pattern on a single crystal silicon layer on said silicon on insulator wafer with at least two finFET transistor patterns;
etching said single crystal silicon layer to form said at least two finFET transistors;
forming a gate dielectric on said single crystal silicon layer;
depositing a protection polysilicon layer on said gate dilectric;
forming a gate pattern on said protection polysilicon layer with a photo resist geometry that keeps said protection polysilicon layer on channels of said at least two finFET transistors and on source and drain diffusions of at least one finFET transistor;
etching said protection polysilicon and removing said protection polysilicon from source and drain regions from all but one of said at least two finFET transistors;
doping said source and drain regions;
forming silicide on said source and drain regions;
depositing a passivation layer;
forming a passivation photo resist pattern with openings over said source and drain regions of said at least two finFET transistors and with a first sensor region opening over channels of said at least two finFET transistors;
etching said passivation layer from said source and drain regions to form probe openings;
etching said passivation layer off from said protection polysilicon layer;
forming a second sensor region photo resist pattern with a second sensor region opening over channel regions of said finFET transistors which do not have polysilicon over said source and drain regions;
etching said passivation layer from said second sensor region opening to expose said gate dialectric forming FET sensors; and
not etching said polysilicon protection layer from said finFET transistor with said polysilicon protection over said source and drain regions to form a gate biasing electrode.

12. The process of claim 11 where said gate biasing electrode polysilicon is silicided.

13. The process of claim 11 further comprising the step:
coating said passivation layer and said gate biasing electrode with a layer of self-assembled molecules (SAMs) with a hydrophilic layer or with a protein.

14. The process of claim 13 where said SAM is a silane, where said hydrophilic layer is Nafion or hydrophilic polyurethane and where said protein is bovine serum albumin.

15. The process of claim 11 further comprising the steps:
depositing an insulation layer on said gate biasing electrode; and
coating said insulation layer with a layer of self-assembled molecules (SAMs) with a hydrophilic layer or with a protein.

16. A process for forming a FET sensor with a gate biasing electrode comprising:
providing a silicon on insulator wafer;
forming an active pattern on a single crystal silicon layer on said silicon on insulator wafer with at least two finFET transistor patterns;
etching said single crystal silicon layer to form said at least two finFET transistors;
forming a gate dielectric on said single crystal silicon layer;
depositing a protection polysilicon layer on said gate dielectric;
forming a gate pattern on said protection polysilicon layer with a photo resist geometry that keeps said protection polysilicon layer on channels all but one of said at least two finFET transistors;
etching said protection polysilicon and removing said protection polysilicon from source and drain regions from of said at least two finFET transistors and removing said protection polysilicon from a channel region of one fin FET transistor;
doping said source and drain regions;
doping said channel region of said one fin FET transistor to form a gate biasing electrode;
forming silicide on said source and drain regions and on said gate biasing electrode;
depositing a passivation layer;
forming a passivation photo resist pattern with openings over said source and drain regions of said at least two finFET transistors and with a first sensor region opening over channels of said at least two finFET transistors;
etching said passivation layer from said source and drain regions to form probe openings;
etching said passivation layer off from said protection polysilicon layer and off from said gate biasing electrode;
forming a second sensor region photo resist pattern with a second sensor region opening over channel regions of said finFET transistors; and
etching said passivation layer from said second sensor region opening to expose said gate dielectric forming FET sensors.

17. The process of claim 16 further comprising the step:
coating said passivation layer and said gate biasing electrode with a layer of self-assembled molecules (SAMs) with a hydrophilic layer or with a protein.

18. The process of claim 17 where said SAM is a silane, where said hydrophilic layer is Nafion or hydrophilic polyurethane and where said protein is bovine serum albumin.

19. The process of claim 16 further comprising the steps:
depositing an insulation layer on said gate biasing electrode; and
coating said insulation layer with a layer of self-assembled molecules (SAMs) with a hydrophilic layer or with a protein.
